(19) United States
(12) Patent Application Publication
(10) Pub. No.: US 2025/0255187 A1
(43) Pub. Date: Aug. 7, 2025

(54) PIEZOELECTRIC-ON-INSULATOR (POI) SUBSTRATE AND METHOD FOR PRODUCING A PIEZOELECTRIC-ON-INSULATOR (POI) SUBSTRATE

(71) Applicant: Soitec, BERNIN (FR)

(72) Inventors: Brice Tavel, BERNIN (FR); Isabelle Bertrand, BERNIN (FR); Christelle Veytizou, BERNIN (FR)

(21) Appl. No.: 18/852,822

(22) PCT Filed: Mar. 30, 2023
(86) PCT No.: PCT/EP2023/058244

§ 371 Date: Sep. 30, 2024

(30) Foreign Application Priority Data
Mar. 30, 2022 (FR) 2202897

(51) Int. Cl. H10N 30/00; H10N 30/03; H10N 30/853

(52) U.S. Cl. CPC H10N 30/708; H10N 30/03; H10N 30/8542

(57) ABSTRACT

A piezoelectric-on-insulator (POI) substrate comprises a support substrate, in particular, a silicon-based substrate, a piezoelectric layer, in particular, a layer of lithium tantalate or lithium niobate, a dielectric layer, in particular, a layer of silicon oxide, sandwiched between the piezoelectric layer and the support substrate, and a trapping structure sandwiched between the dielectric layer and the support substrate. The trapping structure comprises at least two trapping layers that are based on different materials. A particular method may be employed for producing such a piezoelectric-on-insulator substrate.

### CROSS-REFERENCE TO RELATED APPLICATIONS

This application is a national phase entry under 35 U.S.C. § 371 of International Patent Application PCT/EP2023/058244, filed Mar. 30, 2023, designating the United States of America and published as International Patent Publication WO 2023/187030 A1 on Oct. 5, 2023, which claims the benefit under Article 8 of the Patent Cooperation Treaty of French Patent Application Serial No. FR2202897, filed Mar. 30, 2022.

### TECHNICAL FIELD

The present disclosure relates to a piezoelectric-on-insulator (POI) substrate comprising, in this order, a support substrate, a trapping structure, a dielectric layer and a piezoelectric layer, and also to a process for manufacturing such a POI substrate.

### BACKGROUND

Such substrates are known in the prior art, for example, a POI substrate comprising a single-crystal silicon substrate, a polycrystalline silicon trapping structure, a silicon oxide layer and a piezoelectric layer, in particular, a lithium tantalate (LTO) or lithium niobate (LNO) layer. The trapping structure allows losses linked to parasitic conduction effects at the interface between the support substrate and the dielectric layer to be reduced. Specifically, the trapping layer, which is inserted between the support substrate and the dielectric layer, serves to reduce the lifetime of the charges in this region.

However, it is observed that, during heat treatments in the context of or subsequent to the manufacture of the POI substrates, metal elements of the piezoelectric layer, such as lithium, can diffuse through the dielectric layer and the trapping structure as far as the interface with the support substrate. The accumulation of these metal elements reduces the performance qualities of the trapping structure and the suppression of parasitic currents is thus negatively affected.

It is possible to increase the thickness of the trapping layer to increase the number of traps available. However, in this case, parasitic modes are seen in devices using the POI substrate, such as filters, sensors etc.

### BRIEF SUMMARY

The object of the present disclosure is thus to increase the number of traps with less risk of parasitic effects.

The object of the present disclosure is achieved by a piezoelectric-on-insulator (POI) substrate comprising: a support substrate, in particular, a silicon-based substrate, a piezoelectric layer, in particular, a layer of lithium tantalate (LTO) or of lithium niobate (LNO), a dielectric layer, in particular, a silicon oxide layer, sandwiched between the piezoelectric layer and the support substrate, and a trapping structure sandwiched between the dielectric layer and the support substrate, comprising a first trapping layer based on polycrystalline or amorphous or porous silicon, preferably based on polycrystalline silicon. This POI substrate is characterized in that the trapping structure comprises a second trapping layer based on a different material.

The addition of a second trapping layer with a different material in the trapping structure allows the number of traps to be increased, without having to increase the total thickness of the trapping structure to the same extent as would be necessary in the case of a single-material trapping structure.

According to one embodiment, the second trapping layer may be based on silicon carbide. A second layer based on silicon carbide allows efficient reduction of parasitic currents.

According to one embodiment, the second trapping layer based on silicon carbide may be thinner than the first layer. Thus, the provision of a thinner silicon carbide layer allows the number of traps to be increased, while at the same time limiting the appearance of parasitic modes due to the presence of the trapping structure, notably in comparison with a single-material silicon-based trapping layer containing the same number of traps.

According to one embodiment, the second trapping layer based on silicon carbide may have a thickness of less than or equal to 500 nm, in particular, a thickness of less than or equal to 200 nm, more particularly less than or equal to 50 nm. Even at such low thicknesses, there is a sufficient increase in the number of traps.

According to one embodiment, the first silicon-based trapping layer may have a thickness of less than or equal to 2 μm, in particular, less than or equal to 1 μm. By using a second trapping layer, it becomes possible to keep the thickness of the first trapping layer sufficiently low. Thus, parasitic modes due to this layer cannot develop, or at least their contribution remains negligible.

According to one embodiment, the second trapping layer may be formed directly on the first trapping layer. A compact structure may thus be maintained.

According to one embodiment, the first trapping layer is positioned between the support substrate and the second trapping layer. This facilitates the formation of the trapping structure, as a silicon carbide layer is deposited at a lower temperature than a silicon layer.

According to one embodiment, the trapping structure comprises only the first trapping layer and the second trapping layer.

According to one embodiment, the trapping structure is arranged directly on the substrate and the dielectric layer is arranged directly on the trapping structure.

The object of the present disclosure is also achieved by a process for manufacturing a piezoelectric-on-insulator (POI) substrate as described above and comprising the steps of: providing a support substrate, in particular, a silicon-based substrate, providing a substrate comprising a piezoelectric layer, in particular, a substrate comprising lithium tantalate (LTO) or lithium niobate (LNO), forming a trapping structure over the support substrate, forming a dielectric layer, in particular, a silicon oxide layer, over the substrate comprising a piezoelectric layer and/or over the trapping structure, assembling the piezoelectric substrate with the support substrate such that the dielectric layer and the trapping structure are sandwiched between the piezoelectric layer and the support substrate, wherein the formation of the trapping structure comprises the formation of a first layer based on polycrystalline or amorphous or porous silicon, preferably based on polycrystalline silicon, and the formation of a second trapping layer based on a different material.

According to one embodiment, the process for manufacturing a piezoelectric substrate may also comprise a step of: forming a weakened zone inside the piezoelectric layer, in particular, before the assembly step, and fracturing along the weakened zone to separate a part of the piezoelectric layer from the remainder of the substrate comprising the piezoelectric layer after the assembling step in order to transfer the part of the piezoelectric layer onto the support substrate. This process makes it possible to industrially manufacture the POI substrates according to the present disclosure.

### BRIEF DESCRIPTION OF THE DRAWINGS

The present disclosure and its advantages are described in greater detail hereinbelow by means of advantageous exemplary embodiments and with reference notably to the following accompanying figures, in which the reference numbers identify features of the invention.

FIG. 1 diagrammatically represents a piezoelectric-on-insulator (POI) substrate according to a first embodiment of the present disclosure.

FIG. 2 diagrammatically represents a process for manufacturing a piezoelectric-on-insulator (POI) substrate according to a second embodiment of the present disclosure.

### DETAILED DESCRIPTION

The embodiments described are simply possible configurations and it should be borne in mind that the individual features as described above can be provided independently of each other or can be entirely omitted during the implementation of the present disclosure.

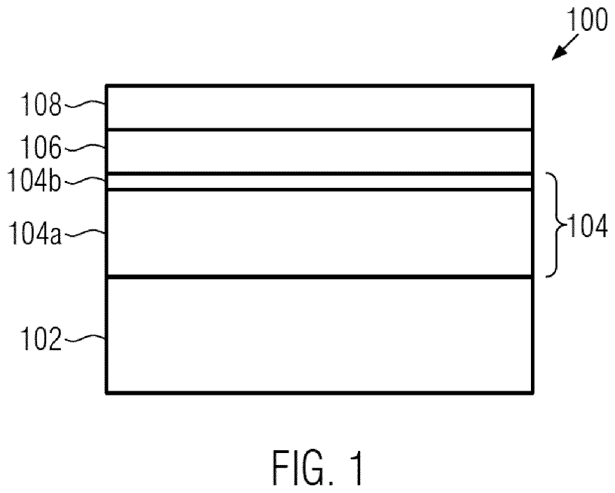

FIG. 1 diagrammatically represents a piezoelectric-on-insulator (POI) substrate 100 according to the first embodiment of the present disclosure.

The piezoelectric-on-insulator substrate 100 comprises a support substrate 102. In this first embodiment, the support substrate 102 is a silicon-based substrate, notably a single-crystal silicon wafer.

A trapping structure 104 is arranged over the support substrate 102. The trapping structure 104 can be in direct contact with the support substrate 102. The trapping structure 104 has a thickness of less than or equal to 2 μm, preferably less than or equal to 1 μm, even more preferably less than or equal to 600 nm.

According to the first embodiment, the trapping structure 104 comprises two layers: a first trapping layer 104a and a second trapping layer 104b, having a material different from the material of the first trapping layer 104a.

According to one variant, the trapping structure 104 comprises only the first trapping layer 104a and the second trapping layer 104b.

The first trapping layer 104a is based on polycrystalline silicon, amorphous silicon or porous silicon. The second trapping layer 104b is based on silicon carbide (SiC). Preferably, these layers are deposited by low-pressure chemical vapor deposition (LPCVD), plasma-enhanced chemical vapor deposition (PECVD) or high-density plasma-enhanced chemical vapor deposition (HDP-CVD).

In this embodiment, the two trapping layers 104a, 104b have different thicknesses. Preferably, the silicon-based trapping layer 104a has a thickness of less than or equal to 2 μm, in particular, a thickness of less than or equal to 1 μm. The second trapping layer 104b based on silicon carbide preferably has a thickness of less than or equal to 500 nm, in particular, a thickness of less than or equal to 200 nm, and more particularly a thickness of less than or equal to 50 nm. According to an example of the present disclosure, the first trapping layer 104a has a thickness of 500 nm and the second trapping layer 104b has a thickness of 50 nm.

A dielectric layer 106 is arranged above, in particular, directly on, the trapping structure 104. The dielectric layer 106 is preferably a layer based on silicon oxide. The dielectric layer 106 preferably has a thickness of between 100 nm and 1 μm, in particular, between 200 nm and 700 nm. The dielectric layer 106 can be formed by CVD deposition or any other appropriate deposition process.

A piezoelectric layer 108 is arranged above, in particular, directly on, the dielectric layer 106. It is preferably a layer of lithium tantalate (LTO) or of lithium niobate (LNO). The piezoelectric layer 108 typically has a thickness of between 200 nm and 1 μm.

Using a trapping structure 104 with two trapping layers 104a, 104b of different materials allows the number of traps to be increased without excessively increasing the thickness of the trapping structure 104.

By adding a second trapping layer 104b of a different, and, in particular, thinner, material, it becomes possible to increase the number of traps while keeping the thickness of the trapping structure low enough to limit the appearance of parasitic modes in final devices such as sensors, filters, etc.

According to a variant, the order of the first trapping layer 104a and the second trapping layer 104b may be reversed. In this case, the second trapping layer, based on silicon carbide, is located between the support substrate 102 and the first trapping layer 104a, which is based on polycrystalline silicon, amorphous silicon or porous silicon.

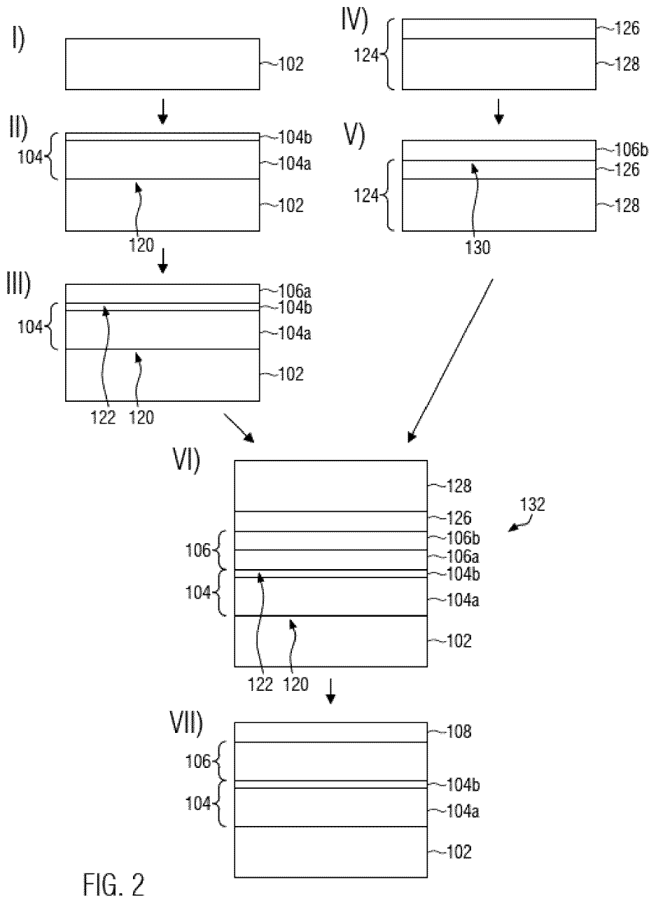

FIG. 2 diagrammatically represents a process for manufacturing a piezoelectric-on-insulator (POI) substrate according to the second embodiment of the present disclosure in order to obtain a POI substrate 100 according to the first embodiment as described above in connection with FIG. 1. The reference numbers already used with reference to FIG. 1 in the context of the description of the POI substrate 100 are reused so as to describe the process of the second embodiment.

The process for manufacturing a piezoelectric-on-insulator (POI) substrate 100 begins with step I) of providing a support substrate 102, notably a silicon-based substrate, in particular, a single-crystal silicon wafer.

According to this second embodiment of the present disclosure, step II) involves the formation of the trapping structure 104 on a free surface 120 of the support substrate 102.

The formation of the trapping structure 104 begins with the formation of a first trapping layer 104a produced by low-pressure chemical vapor deposition (LPCVD). According to variants, the first trapping layer 104a of step II) can be formed by a thermal growth technique or by physical vapor deposition (PVD).

The trapping layer 104a formed on the support substrate 102 is a layer based on polycrystalline silicon, amorphous silicon or porous silicon.

The thickness of the trapping layer 104a is less than or equal to 2 μm, in particular, less than or equal to 1 μm.

Subsequently, a second trapping layer 104b is formed on the first trapping layer 104a. This second trapping layer 104b is based on silicon carbide. The second trapping layer 104b is formed with a thickness less than that of the first trapping layer, preferably with a thickness of less than or equal to 500 nm, in particular, less than or equal to 200 nm, more particularly with a thickness of less than or equal to 50 nm.

The second trapping layer 104b is produced by low-pressure chemical vapor deposition (LPCVD) or plasma-enhanced chemical vapor deposition (PECVD) or high-density plasma-enhanced chemical vapor deposition (HDP-CVD). According to variants, the second trapping layer 104b can be formed during step II) by a thermal growth technique or by physical vapor deposition (PVD). Typically, the second trapping layer 104b is formed at a lower temperature than the first trapping layer 104a.

Prior to the formation of the second trapping layer, one or more treatments of the surface of the first trapping layer 104a may take place, such as polishing, in particular, CMP-type polishing, or activation of the surface by plasma or ozone treatment.

During step III), a dielectric layer 106a is formed on the free surface 122 of the second trapping layer 104b. The dielectric layer 106a is preferably a silicon oxide layer formed by chemical vapor deposition (CVD) or by physical vapor deposition (PVD).

The dielectric layer 106a preferably has a thickness of less than or equal to 1 μm, in particular, less than or equal to 700 nm.

A heat treatment can be performed after the deposition of the dielectric layer 106a in order to densify it.

During step IV), a substrate 124 comprising a piezoelectric layer 126, in particular, a substrate 124 comprising lithium tantalate (LTO) or lithium niobate (LNO), is provided. The piezoelectric layer 126 is, in this embodiment, arranged over a base substrate 128. In an alternative, the piezoelectric layer 126 is a bulk layer and forms the substrate 124 in its entirety.

During step V), a second dielectric layer 106b, in particular, a silicon oxide layer, is produced on the free surface 130 of the piezoelectric layer 126. This layer is produced in the same way as the dielectric layer 106a formed during step III). The thickness is chosen such that the sum of the thicknesses of the two dielectric layers 106a and 106b is between 100 nm and 1 μm, in particular, between 200 nm and 700 nm.

According to a variant, one or more steps of surface treatment of the free surface 130 of the substrate 124 comprising a piezoelectric layer can be performed before the formation of the dielectric layer 106b. For example, a surface activation treatment, such as a plasma treatment and/or an ozone-based treatment, can be performed.

During step VI), the substrate 124 obtained after step V) is assembled with the support substrate 102 obtained in step III) to form an assembly 132 of: support substrate-substrate comprising a piezoelectric layer.

The assembling is performed so that the dielectric layers 106a and 106b are brought into direct contact. The assembling is preferably performed by molecular adhesion.

Once the two substrates are assembled, a step VII) of thinning the assembly 132 is performed to obtain the POI substrate 100 with a thinner piezoelectric layer 108, as illustrated in FIG. 1.

For example, the thinning step can be performed by milling or by a step of forming a weakened zone in the piezoelectric layer 126 before the assembling step VI), so as to delimit the piezoelectric layer 108 to be transferred onto the support substrate 102, followed by fracturing. This step of forming a weakened zone is performed by implanting atomic or ionic species in the piezoelectric layer 126. The atomic or ionic implantation can be performed in such a way that the weakened zone is situated inside the piezoelectric layer 126 and delimits a piezoelectric layer 108 to be transferred from the remainder of the piezoelectric layer 126. Subsequently, a step of fracturing the assembly 132 by supplying thermal and/or mechanical energy at the weakened zone of the piezoelectric layer 126 is subsequently performed so as to obtain the piezoelectric-on-insulator (POI) substrate 100.

According to variants, bonding between the support substrate 102 and the substrate 124 can also be performed between the trapping structure 104 and the dielectric layer 106b, that is to say without performing step III), or between the dielectric layer 106a and the piezoelectric layer 126.

Before producing one or more of the abovementioned layers, one or more steps of cleaning, brushing or polishing the surface directly below can be performed to remove the presence of particles and dust.

1. A piezoelectric-on-insulator (POI) substrate; comprising:
a support substrate;
a piezoelectric layer;
a dielectric layer sandwiched between the piezoelectric layer and the support substrate;
a trapping structure sandwiched between the dielectric layer and the support substrate, the trapping structure including:
a first trapping layer based on polycrystalline or amorphous or porous silicon; and
a second trapping layer based on silicon carbide, the first trapping layer positioned between the support substrate and the second trapping layer.

2. The POI substrate of claim 1, wherein the second trapping layer is thinner than the first trapping layer.

3. The POI substrate of claim 2, wherein the second trapping layer has a thickness of less than or equal to 500 nm.

4. The POI substrate of claim 3, wherein the first trapping layer has a thickness of less than or equal to 2 μm.

5. The POI structure of claim 4, wherein the second trapping layer is disposed directly on the first trapping layer.

6. The POI substrate of claim 5, wherein the trapping structure comprises only the first trapping layer and the second trapping layer.

7. A method of manufacturing a piezoelectric-on-insulator (POI) substrate according to claim 1, the method comprising:
providing a support substrate;
providing a substrate including a piezoelectric layer; and
forming a trapping structure over the support substrate;
forming a dielectric layer over the piezoelectric substrate and/or over the trapping structure; and
assembling the substrate comprising the piezoelectric layer with the support substrate such that the dielectric layer and the trapping structure are sandwiched between the piezoelectric layer and the support substrate;
wherein the forming of the trapping structure includes:
forming a first layer based on polycrystalline or amorphous or porous silicon on the support substrate, and
forming a second trapping layer based on silicon carbide after the forming of the first layer.

8. The method of claim 7, further comprising:
forming a weakened zone inside the piezoelectric layer, and
fracturing along the weakened zone to separate a part of the piezoelectric layer from a remainder of the substrate comprising the piezoelectric layer after the assembling to transfer the part of the piezoelectric layer onto the support substrate.

9. The method of claim 1, further comprising:
selecting the support substrate to comprise a silicon-based support substrate;
selecting the substrate including the piezoelectric layer to comprise a substrate including a lithium tantalate (LTO) layer or a lithium niobate (LNO) layer;
forming the dielectric layer to comprise a silicon oxide layer; and
forming the first layer of the trapping structure to be based on polycrystalline silicon.

10. The POI substrate of claim 1, wherein the support substrate comprises a silicon-based support substrate.

11. The POI substrate of claim 1, wherein the piezoelectric layer comprises a lithium tantalate (LTO) layer or a lithium niobate (LNO) layer.

12. The POI substrate of claim 1, wherein the dielectric layer comprises a silicon oxide layer.

13. The POI substrate of claim 1, wherein the first trapping layer is based on polycrystalline silicon.

14. The POI substrate of claim 1, wherein the second trapping layer has a thickness of less than or equal to 500 nm.

15. The POI substrate of claim 14, wherein the second trapping layer has a thickness of less than or equal to 200 nm.

16. The POI substrate of claim 15, wherein the second trapping layer has a thickness of less than or equal to 50 nm.

17. The POI substrate of claim 1, wherein the first trapping layer has a thickness of less than or equal to 2 μm.

18. The POI substrate of claim 17, wherein the first trapping layer has a thickness of less than or equal to 1 μm.

19. The POI substrate of claim 1, wherein the second trapping layer is disposed directly on the first trapping layer.

20. The POI substrate of claim 1, wherein the trapping structure comprises only the first trapping layer and the second trapping layer.
